(19) United States
(12) Patent Application Publication
(10) Pub. No.: US 2024/0145506 A1
(43) Pub. Date: May 2, 2024

(54) SEMICONDUCTOR PACKAGE AND ELECTRONIC DEVICE

(71) Applicant: SONY SEMICONDUCTOR SOLUTIONS CORPORATION, KANAGAWA (JP)

(72) Inventor: SHUICHI OKA, KANAGAWA (JP)

(21) Appl. No.: 18/548,607

(22) PCT Filed: Jan. 14, 2022
(86) PCT No.: PCT/JP2022/001101

§ 371 Date: Sep. 1, 2023

(30) Foreign Application Priority Data
Mar. 9, 2021 (JP) 2021-036932

(51) Int. Cl. H01L 27/146

(52) U.S. Cl. CPC H01L 27/14618; H01L 27/14636

(57) ABSTRACT

The present technology relates to a semiconductor package and an electronic device capable of providing a semiconductor package capable of enhancing reliability and suppressing characteristic deterioration by adopting a configuration that absorbs a difference in thermal expansion coefficient between a substrate and a cover glass.

A semiconductor package includes a substrate, a chip disposed on the substrate, a frame disposed on the substrate so as to surround the chip, and a cover glass disposed on the frame, in which the frame includes a composition of two or more kinds of materials. Alternatively, the frame has a cavity, and the cavity has different sizes between a side of the substrate and a side of the cover glass. The present technology is applicable to, for example, a semiconductor package including an imaging element as a chip.

### TECHNICAL FIELD

The present technology relates to a semiconductor package and an electronic device, and relates to, for example, a semiconductor package and an electronic device suitable for application to a semiconductor package equipped with an optical element.

### BACKGROUND ART

As a package for an optical device equipped with an optical element such as an imaging element such as a charged-coupled device (CCD) or a complementary metal-oxide semiconductor (CMOS), a light receiving element such as a photo diode (PD), a micro electro mechanical systems (MEMS) element such as an optical switch or a mirror device, a laser diode (LD), a light emitting element such as a laser diode, a light emitting diode (LED), or a vertical cavity surface emitting laser (VCSEL), a package including a resin or/and metal package frame and a cover glass as a translucent member for closing an opening of the package frame is used.

For example, an optical device having a hollow structure and equipped with an optical element is manufactured by mounting an optical element on a package substrate, then mounting a package frame, and bonding a cover glass to an upper surface of a package. It has been proposed that the package frame is configured to prevent flare due to wire bonding, has a structure having a fastening hole for fastening to a housing, or has a structure to function as a heat dissipation path (see, for example, Patent Documents 1 to 3).

### CITATION LIST

### Patent Document

Patent Document 1: Japanese Patent Application Laid-Open No. 2012-217021
Patent Document 2: International Publication No. 2017/090223
Patent Document 3: Japanese Patent Application Laid-Open No. 2013-222772

### SUMMARY OF THE INVENTION

### Problems to be Solved by the Invention

The conventional package frame, which is mainly formed with resin, metal, or a combination thereof, has a possibility of occurrence of crack, peel, warp and the like of the cover glass due to a difference in thermal expansion coefficient (CTE) between the package substrate, the optical element, the package frame, and the cover glass.

When the warp becomes significant, for example, in a case where a CMOS image sensor is used as an optical element, a resolution of decomposition is degraded or an effective pixel region is narrowed. It is desired to suppress the occurrence of crack, peel, warp, and the like of the cover glass due to a different in thermal expansion coefficient.

The present technology has been made in view of such a situation, and makes it possible to suppress occurrence of crack, peel, warp, and the like of a cover glass.

### Solutions to Problems

A first semiconductor package according to one aspect of the present technology includes a substrate, a chip disposed on the substrate, a frame disposed on the substrate so as to surround the chip, and a cover glass disposed on the frame, in which the frame includes a composition of two or more kinds of materials.

A second semiconductor package according to one aspect of the present technology includes a substrate, a chip disposed on the substrate, a frame disposed on the substrate so as to surround the chip, and a cover glass disposed on the frame, in which the frame has a cavity, and the cavity has a size different between a side of the substrate and a side of the cover glass.

A first electronic device according to one aspect of the present technology includes a substrate, an imaging element disposed on the substrate, a frame disposed on the substrate so as to surround the imaging element, a cover glass disposed on the frame, and a processor that processes a signal from the imaging element, in which the frame includes a composition of two or more kinds of materials.

A second electronic device according to one aspect of the present technology includes a substrate, an imaging element disposed on the substrate, a frame disposed on the substrate so as to surround the imaging element, a cover glass disposed on the frame, and a processor that processes a signal from the imaging element, in which the frame has a cavity, and the cavity has a size different between a side of the substrate and a side of the cover glass.

The first semiconductor package according to one aspect of the present technology includes a substrate, a chip disposed on the substrate, a frame disposed on the substrate so as to surround the chip, and a cover glass disposed on the frame, in which the frame includes a composition of two or more kinds of materials.

The second semiconductor package according to one aspect of the present technology includes a substrate, a chip disposed on the substrate, a frame disposed on the substrate so as to surround the chip, and a cover glass disposed on the frame, in which the frame has a cavity, and the cavity has a size different between a side of the substrate and a side of the cover glass.

The first electronic device according to one aspect of the present technology includes a substrate, an imaging element disposed on the substrate, a frame disposed on the substrate so as to surround the imaging element, a cover glass disposed on the frame, and a processor that processes a signal from the imaging element, in which the frame includes a composition of two or more kinds of materials.

The second electronic device according to one aspect of the present technology includes a substrate, an imaging element disposed on the substrate, a frame disposed on the substrate so as to surround the imaging element, a cover glass disposed on the frame, and a processor that processes a signal from the imaging element, in which the frame has a cavity, and the cavity has a size different between a side of the substrate and a side of the cover glass.

### BRIEF DESCRIPTION OF DRAWINGS

FIG. 1 is a plan view showing a configuration of one embodiment of a semiconductor package to which the present technology is applied.

FIG. 2 is a diagram showing a sectional configuration example of the semiconductor package.

FIG. 3 is a diagram showing a configuration example of a frame.

FIG. 4 is a sectional configuration example of a semiconductor package according to a second embodiment.

FIG. 5 is a diagram showing a configuration example of a three-dimensional structure.

FIG. 6 is a diagram showing a configuration example of the frame.

FIG. 7 is a sectional configuration example of a semiconductor package according to a third embodiment.

FIG. 8 is a sectional configuration example of a semiconductor package according to a fourth embodiment.

FIG. 9 is a sectional configuration example of a semiconductor package according to a fifth embodiment.

FIG. 10 is a diagram for describing a manufacturing process of a semiconductor package.

FIG. 11 is a diagram for describing another manufacturing process of the semiconductor package.

FIG. 12 is a diagram showing an example of an electronic device.

FIG. 13 is a diagram for describing a usage example of an imaging device.

FIG. 14 is a diagram showing an example of a schematic configuration of an endoscopic surgery system.

FIG. 15 is a block diagram showing an example of a functional configuration of a camera head and a camera control unit (CCU).

FIG. 16 is a block diagram showing an example of a schematic configuration of a vehicle control system.

FIG. 17 is an explanatory diagram showing an example of installation positions of an outside-vehicle information detecting section and an imaging section.

### MODE FOR CARRYING OUT THE INVENTION

Hereinafter, modes for carrying out the present technology (hereinafter referred to as embodiments) will be described.

### First Embodiment

The present technology described below is applicable to a semiconductor package including a chip of an imaging element such as a charged-coupled device (CCD) or a complementary metal-oxide semiconductor (CMOS). The present invention is be also applicable to a semiconductor package including a chip of an optical element such as a light receiving element such as photo diode (PD), micro electro mechanical system (MEMS) elements such as optical switches and mirror devices, a light emitting element such as a laser diode (LD), a light emitting diode (LED), and a vertical cavity surface emitting laser (VCSEL).

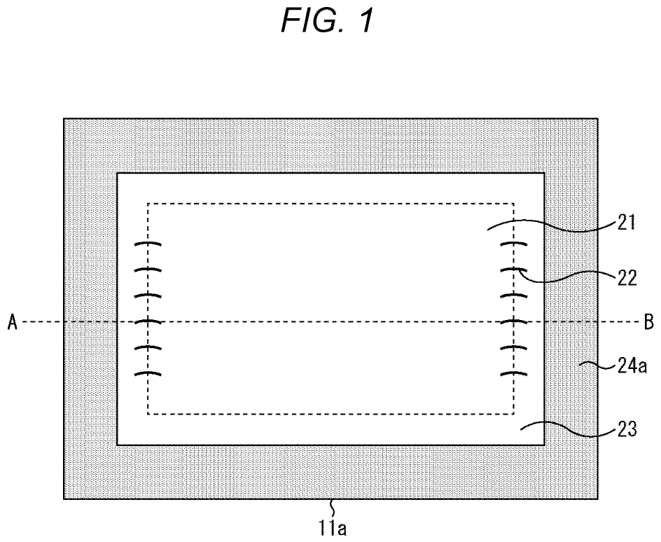

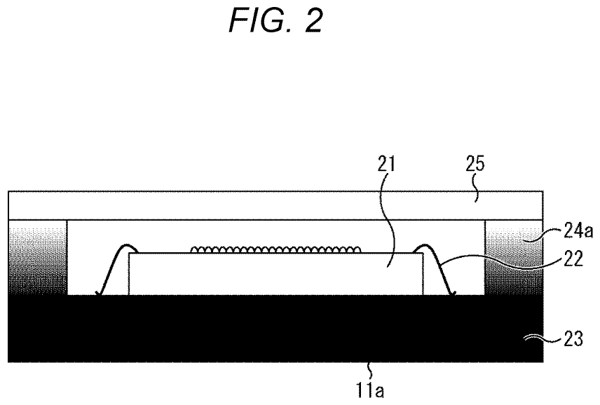

In the following description, a semiconductor package including an imaging element as a chip will be described as an example. FIG. 1 is a plan view showing a configuration example of a semiconductor package 11a according to a first embodiment, and FIG. 2 is a sectional view of the semiconductor package 11a taken along a line A-B in FIG. 1.

In the semiconductor package 11a, a chip of an imaging element 21 is disposed substantially at a center of a substrate 23. The substrate 23 and the imaging element 21 are electrically connected to each other via a bonding wire 22 and a bonding pad (not shown). A frame 24a is disposed so as to surround sides of the imaging element 21. The frame 24a is disposed on the substrate 23. A cover glass 25 (not shown in FIG. 1) is mounted on the frame 24a.

The imaging element 21 is disposed in a space surrounded by the substrate 23, the frame 24a, and the cover glass 25. In FIGS. 1 and 2, an example is shown in which the frame 24a is formed up to the same position as a side surface of the substrate 23 and a side surface of the cover glass 25, but may be formed to have such a size as to protrude outward from the substrate 23 and the cover glass 25. A fastening hole may be provided in the protruding frame 24a to be fastened to a housing. Heat may be dissipated from the protruding frame 24a.

The bonding wire 22 may be enclosed in the frame 24a to suppress flare that can possibly occur due to reflection of light by the bonding wire 22. Other components may be mounted on the substrate 23.

The substrate 23 and the frame 24a are bonded to each other with a predetermined adhesive or the like. The frame 24a and the cover glass 25 are also bonded to each other with a predetermined adhesive or the like. As the substrate 23, for example, an organic substrate or a ceramic substrate is used.

As described above, the substrate 23 and the frame 24a, and the frame 24a and the cover glass 25 are bonded to each other with the adhesive. When the semiconductor package 11a is exposed to heat, there is a possibility that the cover glass 25 is broken, peeled, or warped due to a difference in thermal expansion coefficient (CTE) between the substrate 23, the frame 24a, and the cover glass 25. When the warpage of the cover glass 25 becomes remarkable, there is a possibility that a resolution of decomposition is degraded or an effective pixel region is narrowed.

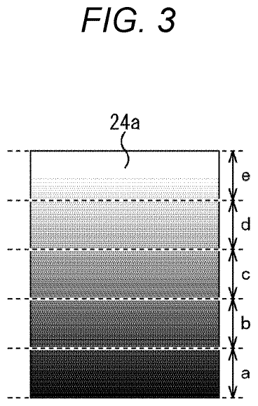

The frame 24a is configured to absorb a difference in thermal expansion coefficient between the substrate 23 and the cover glass 25. The configuration of the frame 24a will be described with reference to FIG. 3. In the drawing, it is assumed that the lower side is a side of the substrate 23 and the upper side is a side of the cover glass 25.

The frame 24a is formed by using a plurality of materials such that a composition of the plurality of materials varies depending on regions. In FIG. 3, a case will be described where the frame 24a is divided into five regions of a region a, a region b, a region c, a region d, and a region e in order from the side of the substrate 23 as an example. Each of the regions has a different mixing ratio of different materials. Here, a material having a value close to the thermal expansion coefficient of the material of the substrate 23 is defined as a material A, and a material having a value close to the thermal expansion coefficient of the cover glass 25 is defined as a material B.

The frame 24a is configured such that the mixing ratio of the material A is greater on a side closer to the substrate 23 of the frame 24a, and the mixing ratio of the material B is greater on a side closer to the cover glass 25 of the frame 24a.

For example, the mixing ratio of the material A and the material B satisfies material A:material B=100:0 in the region a, and material A:material B=75:25 in the region b. In addition, in the region c, the material A:the material B=50:50, in the region d, the material A:the material B=25:75, and in the region e, the material A:the material B=0:100.

Note that the mixing ratios herein illustrated are only examples and are not restrictive. Here, the description has been given assuming that the material A is a material having a value close to the thermal expansion coefficient of the material of the substrate 23 and the material B is a material having a value close to the thermal expansion coefficient of the material of the cover glass 25. However, for example, the mixing ratio may be set such that the thermal expansion coefficient when the material A and the material B are mixed at a predetermined mixing ratio becomes a value close to the thermal expansion coefficient of the substrate 23, and the material A and the material B mixed at such a mixing ratio may be disposed on the side of the substrate 23 (region a).

Similarly, for example, the mixing ratio may be set such that the thermal expansion coefficient when the material A and the material B are mixed at a predetermined mixing ratio becomes a value close to the thermal expansion coefficient of the cover glass 25, and the material A and the material B mixed at such a mixing ratio may be disposed on the side of the cover glass 25 (region e).

Here, a case where the material A and the material B are divided into five regions has been described as an example. However, the number of regions having different mixing ratios of the material A and the material B may be five or more or five or less. The mixing ratio of the material A and the material B may be configured to continuously change. For example, the mixing ratio of the material A from the side of the substrate 23 of the frame 24a to the side of the cover glass 25 may continuously change from 100 to 0, in other words, the mixing ratio of the material B may continuously change from 0 to 100.

Here, a case where two types of materials are mixed has been described as an example of the material constituting the frame 24a, but the types of materials to be mixed are not limited to two types, and the present technology is also applicable to a case where two or more materials are mixed.

A plurality of materials is mixed at a mixing ratio that matches (substantially matches) the thermal expansion coefficient of the substrate 23 in the frame 24a on the side of the substrate 23, and a plurality of materials is mixed at a mixing ratio that matches (substantially matches) the thermal expansion coefficient of the cover glass 25 in the frame 24a on the side of the cover glass 25. The mixing ratio of the plurality of materials constituting the frame 24a is determined such that the thermal expansion coefficient gradually changes from the side of the substrate 23 to the side of the cover glass 25 of the frame 24a.

As described above, by forming the frame 24 by adjusting the mixing ratio of the material A and the material B constituting the frame 24a, the frame 24a formed with the material substantially matching the thermal expansion coefficient of the substrate 23 can be disposed on the side of the substrate 23, and the frame 24a formed with the material substantially matching the thermal expansion coefficient of the cover glass 25 can be disposed on the side of the cover glass 25.

As described above, by arranging the material having substantially the same thermal expansion coefficient near a bonding surface, a force generated by the difference in thermal expansion coefficient between the substrate 23 and the cover glass 25 can be absorbed by the frame 24a, and, for example, breakage of the cover glass 25 as described above can be prevented.

As the material of the frame 24a, for example, an insulating resin material such as glass epoxy resin can be used. As the adhesive used for bonding the substrate 23 and the frame 24a, for example, an insulating resin material such as an epoxy resin can be used.

In a case where the frame 24a is formed with a glass epoxy resin, the thermal expansion coefficient may be adjusted in a thickness direction of the frame 24a by adjusting a content ratio of a filler contained in the resin component. As for the frame 24a, the thermal expansion coefficient of the frame 24a may be adjusted by adjusting the mixing ratio of any two or more types from among resin such as glass epoxy, metal, or ceramic.

The frame 24a can be formed by using a device used for forming a three-dimensional object called a so-called 3D printer. The method of the 3D printer may be any method. A 3D printer is a device capable of forming a three-dimensional object by laminating sectional shapes. Such a 3D printer can be used to form the frame 24a having different mixing ratios of the plurality of materials.

For example, when the frame 24a is formed by a 3D printer, the frame 24a can be formed by changing the mixing ratio of the materials every time a sectional shape is laminated.

Specifically, in a case where the frame 24a is formed with glass epoxy and metal, when the frame 24a on the side of the substrate 23 is formed, the mixing ratio of glass epoxy is increased, and the sectional shapes of the frame 24a is laminated while gradually increasing a metal content ratio, and thus the frame 24a in which the mixing ratio is continuously changed can be formed.

Although details will be described later, when the semiconductor package 11a is formed, the frame 24a may be formed by the 3D printer, and the formed frame 24a and the substrate 23 may be bonded with the adhesive, or when the frame 24a is formed by the 3D printer, the substrate 23 may be placed in the 3D printer, and the frame 24a may be directly formed on the substrate 23. By directly forming the frame 24a on the substrate 23, the substrate 23 and the frame 24a can be integrated. The configuration in which the substrate 23 and the frame 24a are integrated eliminates the need for the adhesive for bonding the substrate 23 and the frame 24a and can remove an influence of the adhesive.

### Second Embodiment

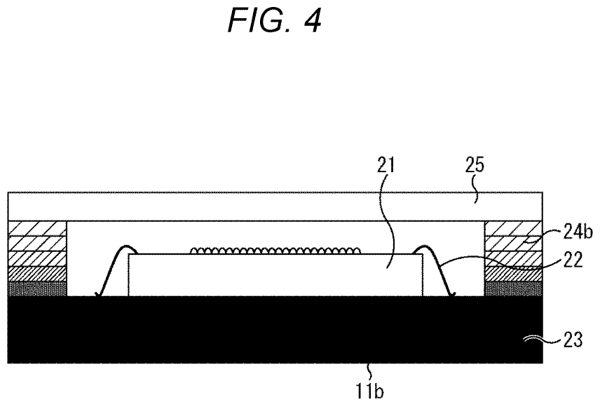

FIG. 4 is a sectional configuration example of a semiconductor package 11b according to a second embodiment. A planar configuration of the semiconductor package 11b according to the second embodiment is similar to a planar configuration of the semiconductor package 11a according to the first embodiment, as shown in FIG. 1, and thus illustration and description are omitted here. In the semiconductor package 11b according to the second embodiment, portions similar to portions of the semiconductor package 11a according to the first embodiment shown in FIG. 2 are denoted by similar reference signs, and the description thereof will be omitted.

A frame 24b of the semiconductor package 11b according to the second embodiment has a lattice structure, which is different from the semiconductor package 11a according to the first embodiment, and the rest is similar.

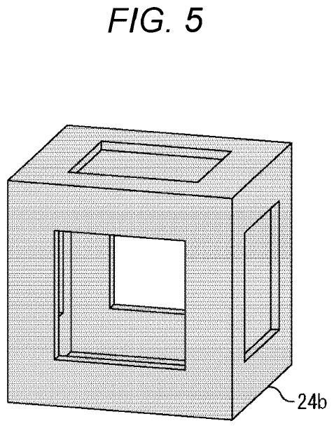

The frame 24b of the semiconductor package 11b has a lattice structure, and a pitch of the lattice structure is different between the side of the substrate 23 and the side of the cover glass 25. The lattice structure is generally a structure in which lattices branched like a tree are periodically arranged. For example, a structure will be described, as an example, where a plurality of cubes as shown in FIG. 5, which is a plurality of three-dimensional structures each having a cavity in a central portion, is arranged (stacked) in a vertical direction, a horizontal direction, and a depth direction. Note that a shape other than the shape shown in FIG. 5 is also applicable to the present technology.

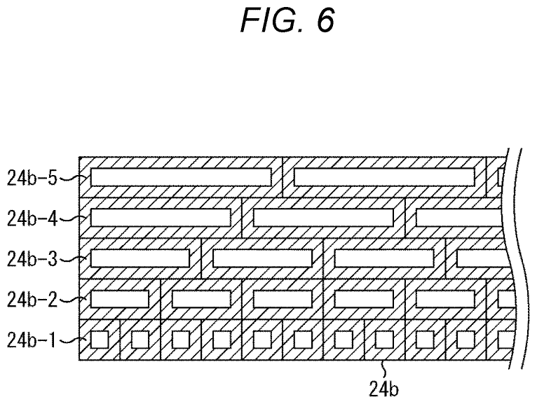

The frame 24b has, for example, a structure in which three-dimensional structures having different sizes of cavities at the central portion are stacked in the vertical, horizontal, and depth directions with respect to the object of the lattice structure (hereinafter, referred to as a three-dimensional structure) shown in FIG. 5. FIG. 6 shows a configuration of an example of the frame 24b. FIG. 6 shows one side surface of the frame 24b, and a case is illustrated as an example where the frame 24b is divided into five layers of frames 24b-1 to 24b-5. It is assumed that the side of the frame 24b-1 is the side of the substrate 23, and the side of the frame 24b-5 is the side of the cover glass 25.

The frame 24b-1 is formed with a smaller three-dimensional structure. In a case where the of three-dimensional structure constituting the frame 24b-1 is a three-dimensional structure as a reference (hereinafter, referred to as a reference three-dimensional structure), the frame 24b-2 is formed with a three-dimensional structure having a lateral side twice as long as a lateral side of the reference three-dimensional structure. The frame 24b-3 is formed with a three-dimensional structure having a lateral side three times as long as the lateral side of the reference three-dimensional structure. The frame 24b-4 is formed with a three-dimensional structure having a lateral side four times as long as the lateral side of the reference three-dimensional structure. The frame 24b-5 is formed with a three-dimensional structure having a lateral side five times as long as the lateral side of the reference three-dimensional structure.

In the example shown in FIG. 6, a case has been described where the sides of the frames 24b-1 to 24b-5 in the vertical direction are the same. However, the sides in the vertical direction may also have different lengths depending on the layer. Here, a case has been described, as an example, where the length of the side is changed by two to five times in the lateral direction of the reference three-dimensional structure, but the length may be changed by a different rate.

The frame 24b having such a structure can be formed by using a 3D printer. In a case where the frame 24b is formed by the 3D printer, the frame 24b having the shape as shown in FIG. 6 can be also integrally formed since the frame is formed while the sectional shapes are laminated as described above. That is, although the layers are described, each of the layers is not bonded with the adhesive or the like, but is continuously formed.

In the structure of the frame 24b shown in FIG. 6, the size of a cavity portion of each layer is configured to be different. In a case where the sizes of the cavity portions are compared, the following relationship is established.

In a case where frame 24b-1<frame 24b-3<frame 24b-3<frame 24b-4<frame 24b-5 is established, the frame 24b on the side closer to the substrate 23 has fewer cavity portions, and the frame 24b on the side closer to the cover glass 25 has more cavity portions. The description will be continued assuming that a part having fewer (smaller) cavity portions is a part having sparse cavity portions, and a part having more (larger) cavity portions is a part having dense cavity portions.

The three-dimensional structures constituting the frame 24b have the following relationship in terms of density.

In a case where frame 24b-1>frame 24b-3>frame 24b-3>frame 24b-4>frame 24b-5 is established, the three-dimensional structures are configured to be dense in the frame 24b on the side closer to the substrate 23, and the three-dimensional structures are configured to be sparse in the frame 24b on the side closer to the cover glass 25.

It can be said that the side having more cavity portions (the side where the cavity portions are dense), in other words, the side where the three-dimensional structures are configured to be sparse, has a structure that is likely to change with thermal expansion when the three-dimensional structures are thermally expanded. Therefore, the frame 24b in which the three-dimensional structures are configured to be sparse as described above is disposed so as to be situated on the side where the thermal expansion coefficient is high.

In FIG. 6, an example is shown in which the cavity portion gradually increases in size from the side of the substrate 23 to the side of the cover glass 25, but the cavity portion may gradually decrease in size. The density of the cavities are appropriately set in accordance with the materials of the substrate 23 and the cover glass 25, the material of the frame 24b, and the like.

As described above, by adopting a configuration in which the three-dimensional structures constituting the frame 24b are provided with density, in other words, by adopting a configuration in which the cavity portions are provided with a change in density, the force generated when the semiconductor package 11b is exposed to heat due to the difference in thermal expansion coefficient between the substrate 23 and the cover glass 25 can be absorbed by the frame 24b.

The arrangement of the three-dimensional structures shown in FIG. 6 is an example, and is not a description indicating limitation. The shape and size of the three-dimensional structure itself may be a shape and size other than those exemplified. For example, FIG. 6 exemplifies a case where the density of the three-dimensional structures is adjusted by adjusting a width of the three-dimensional structures. However, the density of the three-dimensional structures may be adjusted by adjusting intervals between the three-dimensional structures.

For example, the frame 24b has a configuration in which three-dimensional structures as shown in FIG. 5 are stacked, but the three-dimensional structures are disposed at predetermined intervals, and the intervals are different for each layer.

For example, in the frame 24b-1, the three-dimensional structures are disposed at intervals, and in the frame 24b-2, the three-dimensional structures are disposed at intervals corresponding to one three-dimensional structure. Similarly, in the frame 24b-3, the three-dimensional structures are disposed at intervals corresponding to two three-dimensional structures, in the frame 24b-4, the three-dimensional structures are disposed at intervals corresponding to three three-dimensional structures, and in the frame 24b-5, the three-dimensional structures are disposed at intervals corresponding to four three-dimensional structures.

In this manner, by changing the intervals in the arrangement of the three-dimensional structures, a part where the three-dimensional structures are sparse and a part where the three-dimensional structures are dense may be created in the frame 24b. In this case, the frame 24b can be formed by stacking three-dimensional structures having no cavity.

As described above, the frame 24b has a cavity, and the density (size) of the cavity portions is changed depending on the position, and thus the force generated by the difference in thermal expansion coefficient between the substrate 23 and the cover glass 25 can be absorbed by the frame 24b. Therefore, for example, breakage of the cover glass 25 as described above can be prevented.

### Third Embodiment

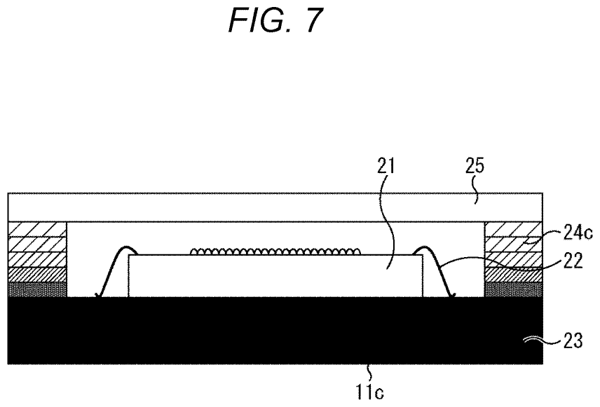

FIG. 7 is a sectional view showing a configuration example of a semiconductor package 11c according to a third embodiment. The semiconductor package 11c according to the third embodiment has a configuration combining the semiconductor package 11a (FIG. 2) according to the first embodiment and the semiconductor package 11b (FIG. 4) according to the second embodiment.

In the same manner as the frame 24b of the semiconductor package 11b (FIG. 4) according to the second embodiment, the frame 24c of the semiconductor package 11c has a structure in which the three-dimensional structures are formed in a sparse and dense manner (cavity portions are sparse and dense). In the same manner as the frame 24a of the semiconductor package 11a (FIG. 2) according to the first embodiment, the frame 24c is formed with a plurality of materials, and the composition of the plurality of materials is configured to gradually change.

As described above, the three-dimensional structure constituting the frame 24c is provided with density, and the mixing ratio of the materials is changed in the thickness direction. Therefore, the force generated when the semiconductor package 11c is exposed to heat due to the difference in thermal expansion coefficient between the substrate 23 and the cover glass 25 can be absorbed by the frame 24c.

### Fourth Embodiment

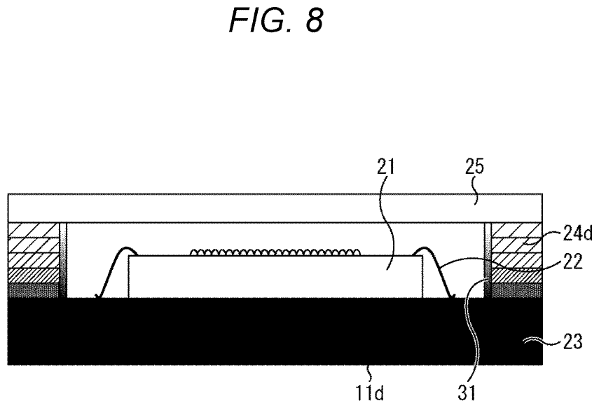

FIG. 8 is a sectional view showing a configuration example of a semiconductor package 11d according to the third embodiment.

The frame 24d of the semiconductor package 11d shown in FIG. 8 is different in that an inner stopper 31 is added to the frame 24b of the semiconductor package lib according to the second embodiment shown in FIG. 4, and the rest is similar.

Since the frame 24b of the semiconductor package lib according to the second embodiment shown in FIG. 4 has the cavity portions, there is a possibility that dust and moisture enter the space surrounded by the substrate 23, the frame 24b, and the cover glass 25, and affect the imaging element 21. The frame 24d of the semiconductor package 11d shown in FIG. 8 has a configuration in which the inner stopper 31 that prevents dust and moisture from entering is added in the space surrounded by the substrate 23, the frame 24d, and the cover glass 25.

In the semiconductor package 11d shown in FIG. 8, since the imaging element 21 is disposed in the space surrounded by the substrate 23, the inner stopper 31, and the cover glass 25, this configuration can prevent dust and moisture from entering the space in which the imaging element 21 is disposed.

The inner stopper 31 is formed as a side wall without a cavity portion on a side where the imaging element 21 is disposed, that is, inside the frame 24d.

The inner stopper 31 may be integrally formed with the frame 24d, or may be bonded to the substrate 23 and the cover glass 25 so as not to be in contact with the frame 24d. In a case where the imaging element 21 is configured not to be in contact with the frame 24d, the imaging element is configured to be surrounded by the frame 24d and the inner stopper 31.

The inner stopper 31 may have the same configuration as the frame 24a of the semiconductor package 11a according to the first embodiment, may be configured by using different materials, and may be configured such that the mixing ratio of the materials changes. Such a configuration allows the inner stopper 31 to also absorb the force generated when the semiconductor package 11d is exposed to heat due to the difference in thermal expansion coefficient between the substrate 23 and the cover glass 25.

Note that the frame 24d may have the same configuration as the frame 24c of the semiconductor package 11c according to the third embodiment, and the inner stopper 31 may be added to the frame 24c.

As described above, the three-dimensional structure constituting the frame 24d is provided with density and includes the inner stopper 31. Therefore, the force generated when the semiconductor package 11d is exposed to heat due to the difference in thermal expansion coefficient between the substrate 23 and the cover glass 25 can be absorbed by the frame 24d, and dust and the like can be prevented from entering the space in which the imaging element 21 is disposed.

### Fifth Embodiment

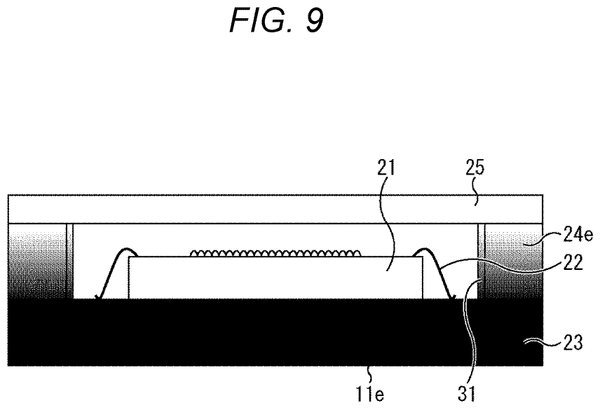

FIG. 9 is a sectional view showing a configuration example of a semiconductor package 11e according to a fifth embodiment. The semiconductor package 11e according to the fifth embodiment has a configuration combining the semiconductor package 11a (FIG. 2) according to the first embodiment and the semiconductor package 11d (FIG. 8) according to the fourth embodiment.

In the same manner as the frame 24a of the semiconductor package 11a (FIG. 2) according to the first embodiment, the frame 24e of the semiconductor package 11e according to the fifth embodiment has a structure in which a plurality of materials is used and a mixing ratio of the materials gradually changes. In the same manner as the frame 24d of the semiconductor package 11d (FIG. 8) according to the fourth embodiment, the frame 24e includes the inner stopper 31.

As described above, the frame 24e is configured by using the plurality of materials of which mixing ratio gradually changes, and the frame 24e includes the inner stopper 31. Therefore, the force generated when the semiconductor package 11e is exposed to heat due to the difference in thermal expansion coefficient between the substrate 23 and the cover glass 25 can be absorbed by the frame 24e, and it is possible to obtain a stronger configuration in which dust and the like are prevented from entering the space in which the imaging element 21 is disposed.

In the first to fifth embodiments, a case has been described, as an example, where the imaging element 21 is disposed in the semiconductor package 11. However, the present technology is also applicable to the semiconductor package 11 in which a chip other than the imaging element 21 is disposed. That is, the present technology is applicable to the semiconductor package 11 in which any chip is disposed.

<Manufacturing of Semiconductor Package 11>

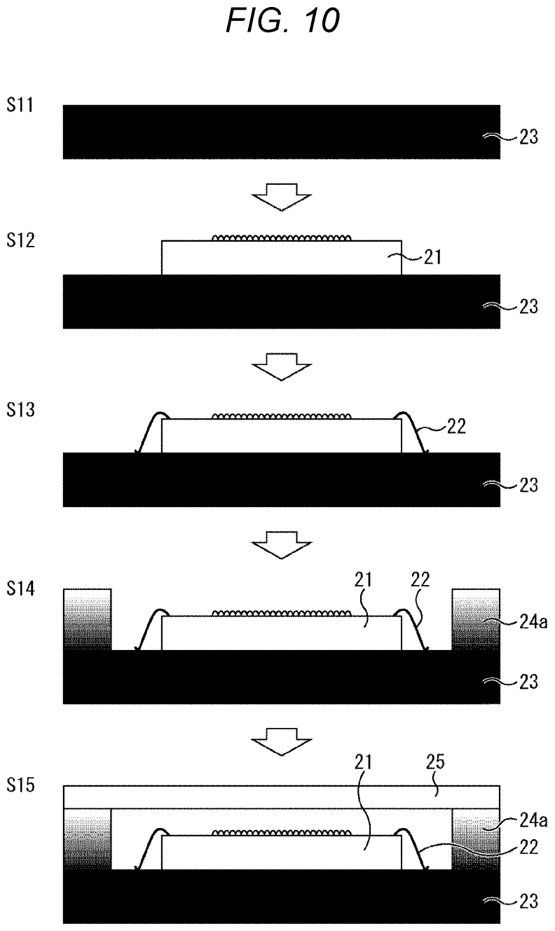

The manufacturing of the semiconductor package 11a according to the first embodiment will be described with reference to FIG. 10.

In step S11, the substrate 23 is prepared. In step S12, the imaging element 21 is fixed onto the substrate 23 (die bonding). In step S13, the imaging element 21 and the pad formed on the substrate 23 are connected by the bonding wire 22.

In step S14, the frame 24a is bonded with the adhesive to the outside of a region of the substrate 23 where the imaging element 21 is disposed. The frame 24a is prepared by molding in another step by using, for example, a 3D printer. In step S15, the cover glass 25 is bonded onto the frame 24a with the adhesive.

In this way, the semiconductor package 11a is manufactured. The semiconductor packages 11b to 11e according to the second to fifth embodiments can be also basically manufactured in a similar process. Note that the manufacturing process described here is an example, and the semiconductor package 11 may be manufactured by another manufacturing process. For example, the process may be a process of bonding the substrate 23 and the frame 24 or bonding the frame 24 and the cover glass 25 without using the adhesive.

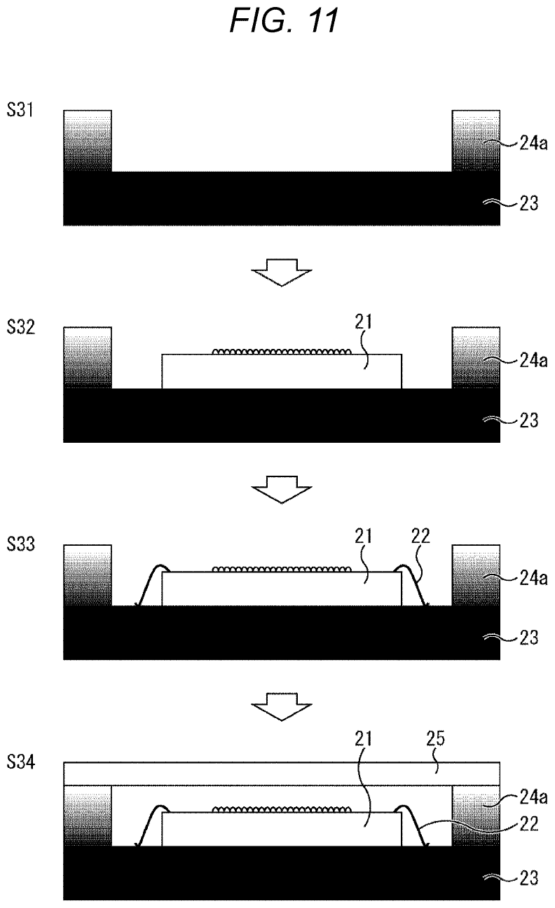

Another manufacturing process of the semiconductor package 11a according to the first embodiment will be described with reference to FIG. 11.

In step S31, the substrate 23 in which the substrate 23 and the frame 24a are integrated is prepared. For example, the frame 24a is formed on the substrate 23 by using a 3D printer, and the substrate 23 on which the frame 24a is formed is prepared.

In step S32, the imaging element 21 is fixed to a region surrounded by the frame 24a on the substrate 23 (die bonding). In step S33, the imaging element 21 and the pad formed on the substrate 23 are connected by the bonding wire 22. In step S34, the cover glass 25 is bonded onto the frame 24a with the adhesive.

In this way, the semiconductor package 11a is manufactured. The semiconductor packages lib to 11e according to the second to fifth embodiments can be also basically manufactured in a similar process. Note that the manufacturing process described here is an example, and the semiconductor package 11 may be manufactured by another manufacturing process. For example, the process may be a process of bonding the frame 24 and the cover glass 25 without using the adhesive.

<Configuration of Electronic Device>

The semiconductor package 11 including the imaging element 21 described above is applicable to various electronic devices such as, for example, an imaging device such as a digital still camera and a digital video camera, a mobile phone with an imaging function, or other devices having an imaging function.

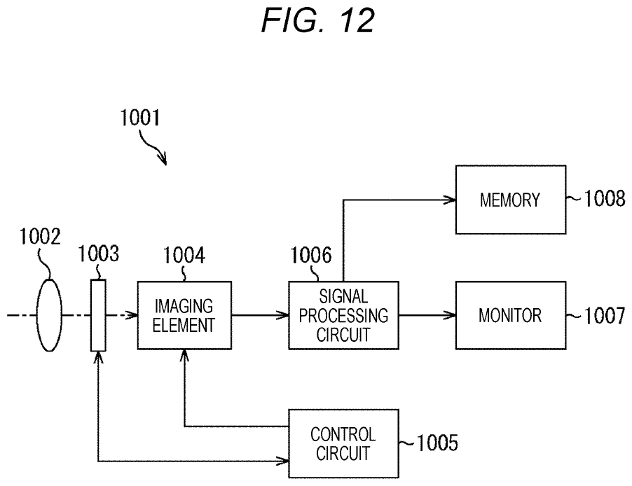

FIG. 12 is a block diagram showing a configuration example of the imaging device as the electronic device. An imaging device 1001 illustrated in FIG. 12 includes an optical system 1002, a shutter device 1003, an imaging element 1004, a drive circuit 1005, a signal processing circuit 1006, a monitor 1007, and a memory 1008, and can capture still images and moving images.

The optical system 1002 has one or more lenses, and guides light (incident light) from a subject to the imaging element 1004 and forms as an image on a light receiving surface of the imaging element 1004.

The shutter device 1003 is disposed between the optical system 1002 and the imaging element 1004, and controls a light irradiation period and a shading period with respect to the imaging element 1004 in accordance with the control of the drive circuit 1005.

The imaging element 1004 includes a package including the above-described imaging element. The imaging element 1004 accumulates signal charges for a certain period of time in accordance with light formed as an image on the light receiving surface via the optical system 1002 and the shutter device 1003. The signal charges accumulated in the imaging element 1004 are transferred in accordance with a drive signal (a timing signal) supplied from the drive circuit 1005.

The drive circuit 1005 outputs a drive signal for controlling a transfer operation of the imaging element 1004 and a shutter operation of the shutter device 1003, to drive the imaging element 1004 and the shutter device 1003.

The signal processing circuit 1006 performs various kinds of signal processing on the signal charges outputted from the imaging element 1004. The image (image data) obtained by the signal processing applied by the signal processing circuit 1006 is supplied to the monitor 1007 to be displayed or supplied to the memory 1008 to be stored (recorded).

<Usage Example of Semiconductor Package Including Imaging Element>

Next, a usage example of (the imaging device including) the semiconductor package 11 including the imaging element 21 to which the present technology is applied will be described.

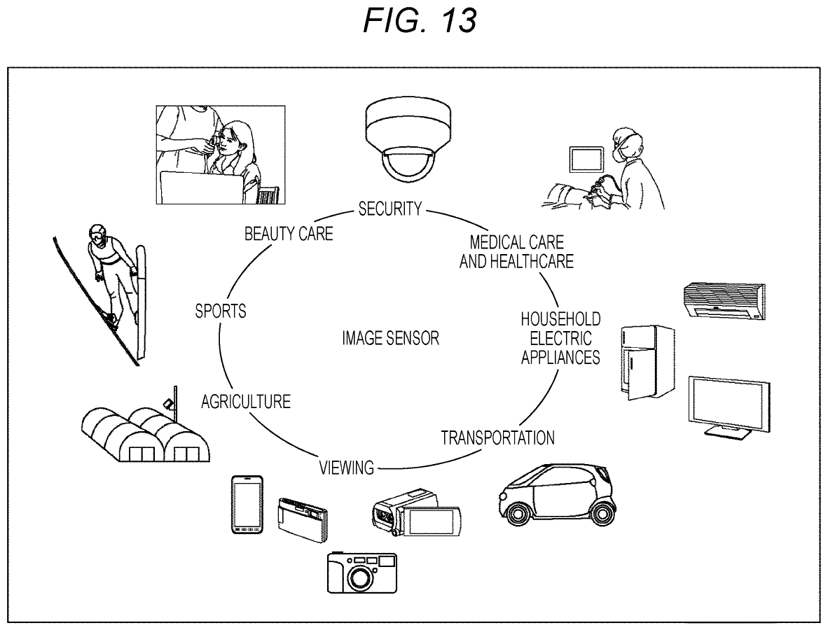

FIG. 13 shows the usage example of (the imaging device including) the semiconductor package 11 including the imaging element 21 to which the present technology is applied.

The imaging devices according to the above-described embodiments can be used in various cases of sensing light such as visible light, infrared light, ultraviolet light, and X-ray, as described below, for example. The above embodiments can be also used, for example, for devices used in the field of viewing in which images for viewing are captured, the field of transportation, the field of household electric appliances, the field of medical care and healthcare, the field of security, the field of beauty care, the field of sports, the field of agriculture, and the like.

Specifically, in the viewing field, the above embodiments are applicable to, for example, devices for capturing an image to be viewed, such as a digital camera, a smartphone, and a mobile phone with a camera function.

In the field of transportation, for example, for safe driving such as automatic stop, recognition of a state of a driver, and the like, the above embodiments are applicable to devices used for transportation, such as vehicle-mounted sensors that capture an image in front, rear, surroundings, interior, and the like of an automobile, monitoring cameras that monitor traveling vehicles and roads, and distance measurement sensors that measure a distance between vehicles.

In the field of household electric appliances, for example, in order to capture an image of a user's gesture and operate a device in accordance with the gesture, the above embodiments are applicable to devices used in household electric appliances such as TV receivers, refrigerators, and air conditioners.

In the field of medical care and healthcare, for example, the above embodiments are applicable to devices used for medical care and healthcare, such as endoscopes and devices that perform angiography by receiving infrared light.

In the security field, the above embodiments are applicable to security devices such as a security monitoring camera and a personal authentication camera, for example.

In the field of beauty care, for example, the above embodiments are applicable to devices used for beauty care, such as skin measuring instruments for image capturing of skin or microscopes for image capturing of scalp.

In the sports field, the above embodiments are applicable to sports devices such as an action camera and a wearable camera for sports, for example.

In the agricultural field, the above embodiments are applicable to agricultural devices such as a camera for monitoring a land and crop state, for example.

The present technology is applicable to other various products.

<Examples of Application to Endoscopic Surgery System>

The technology of the present disclosure (present technology) is applicable to various products. For example, the technology of the present disclosure may be applied to an endoscopic surgery system.

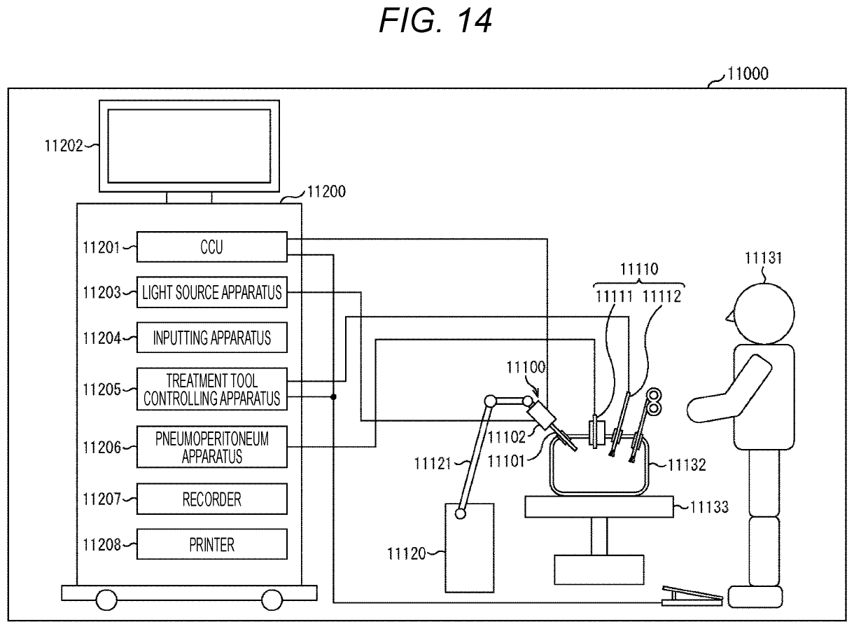

FIG. 14 is a diagram showing an example of a schematic configuration of an endoscopic surgery system to which the technology of the present disclosure (present technology) can be applied.

FIG. 14 shows a state in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

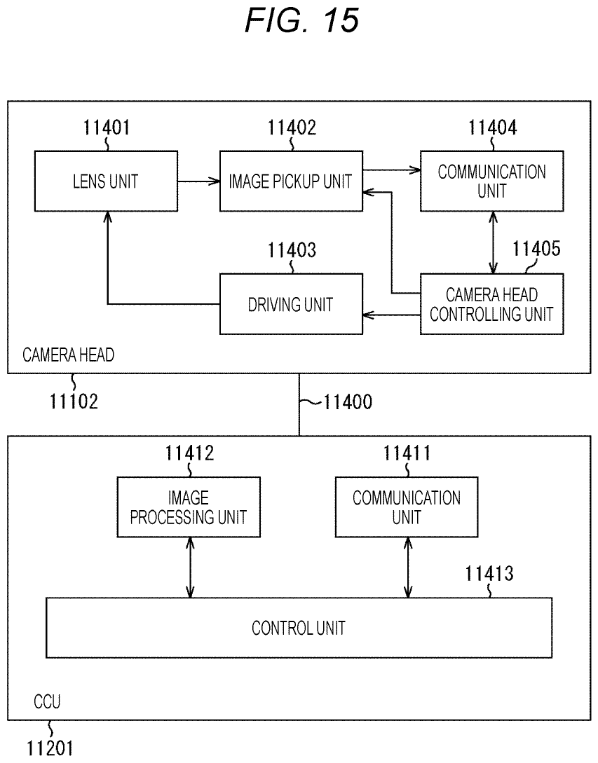

FIG. 15 is a block diagram showing an example of a functional configuration of the camera head 11102 and the CCU 11201 shown in FIG. 14.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

<Examples of Application to Mobile Body>

The technology of the present disclosure (present technology) is applicable to various products. For example, the technology of the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

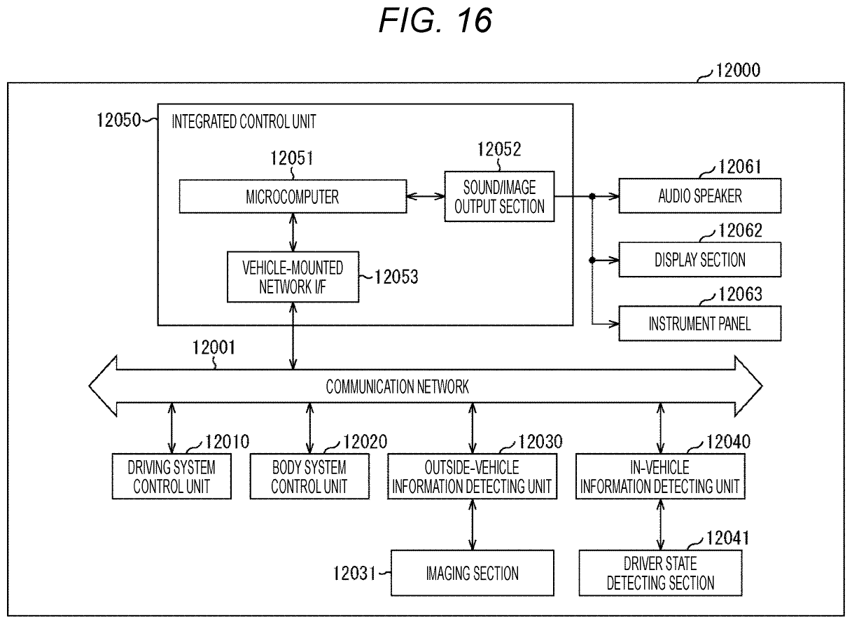

FIG. 16 is a block diagram showing an example of a schematic configuration of a vehicle control system as an example of a mobile body control system to which the technology of the present disclosure can be applied.

The vehicle control system 12000 includes a plurality of electronic control units connected to each other via a communication network 12001. In the example shown in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are exemplified as the output devices. The display section 12062 may, for example, include at least one of an on-board display and a head-up display.

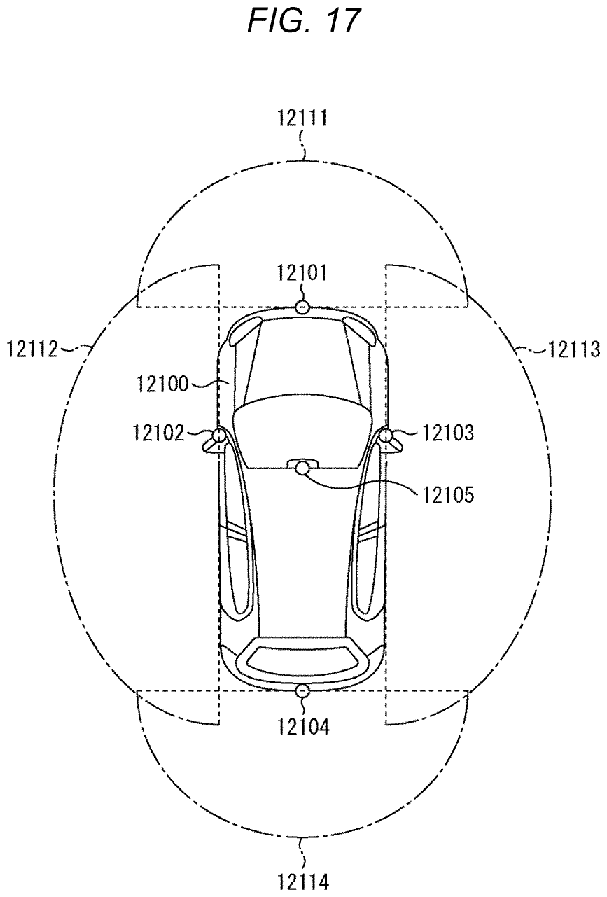

FIG. 17 is a diagram showing an example of an installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 17 shows an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

It should be noted that embodiments of the present technology are not limited to the above embodiments, and various modifications are possible without departing from the gist of the present technology.

Furthermore, effects herein described are merely examples and are not limited, and there may be other effects.

Note that the present disclosure is not limited to the above embodiments, and various modifications can be made without departing from the gist of the present disclosure. Furthermore, the effects herein described are merely examples and are not limited, and there may be other effects.

Note that the present technology can adopt the following configurations.

(1)

A semiconductor package includes a substrate, a chip disposed on the substrate, a frame disposed on the substrate so as to surround the chip, and a cover glass disposed on the frame, in which the frame includes a composition of two or more kinds of materials.

(2)

In the semiconductor package according to (1), the composition of the materials is different between a side of the substrate and a side of the cover glass of the frame.

(3)

In the semiconductor package according to (1) or (2), a thermal expansion coefficient of the frame on the side of the substrate is substantially same as a thermal expansion coefficient of the substrate, and a thermal expansion coefficient of the frame on the side of the cover glass is substantially same as a thermal expansion coefficient of the cover glass.

(4)

In the semiconductor package according to (3), the thermal expansion coefficient of the frame gradually changes from the side of the substrate to the side of the cover glass.

(5)

In the semiconductor package according to any of (1) to (4), the materials include any of a resin, a metal, or a ceramic.

(6)

In the semiconductor package according to any of (1) to (5), the frame and the substrate are integrally configured.

(7)

In the semiconductor package according to any of (1) to (6), the frame has a structure having a cavity, and the cavity has a size different between the side of the substrate and the side of the cover glass.

(8)

In the semiconductor package according to any of (1) to (7),
the chip includes an imaging element.

(9)

A semiconductor package includes a substrate, a chip disposed on the substrate, a frame disposed on the substrate so as to surround the chip, and a cover glass disposed on the frame, in which the frame has a cavity, and the cavity has a size different between a side of the substrate and a side of the cover glass.

(10)

In the semiconductor package according to (9), the size of the cavity gradually increases or decreases between the side of the substrate and the side of the cover glass of the frame.

(11)

In the semiconductor package according to (9) or (10), a side wall having no cavity is disposed on a side of the chip of the frame.

(12)

In the semiconductor package according to any of (9) to (11), the frame includes a composition of two or more kinds of materials, and the composition of the materials of the frame gradually changes from the side of the substrate to the side of the cover glass.

(13)

In the semiconductor package according to (12), the materials include any of a resin, a metal, or a ceramic.

(14)

In the semiconductor package according to any of (9) to (13),
the chip includes an imaging element.

(15)

An electronic device includes a substrate, an imaging element disposed on the substrate, a frame disposed on the substrate so as to surround the imaging element, a cover glass disposed on the frame, and a processor that processes a signal from the imaging element, in which the frame includes a composition of two or more kinds of materials.

(16)

An electronic device includes a substrate, an imaging element disposed on the substrate, a frame disposed on the substrate so as to surround the imaging element, a cover glass disposed on the frame, and a processor that processes a signal from the imaging element, in which the frame has a cavity, and the cavity has a size different between a side of the substrate and a side of the cover glass.

### REFERENCE SIGNS LIST

11 Semiconductor package
21 Imaging element
22 Bonding wire
23 Substrate
24 Frame
25 Cover glass
31 Inner stopper
1001 Imaging device
1002 Optical system
1003 Shutter device
1004 Imaging element
1005 Drive circuit
1006 Signal processing circuit
1007 Monitor
1008 Memory

1. A semiconductor package comprising:
a substrate;
a chip disposed on the substrate;
a frame disposed on the substrate so as to surround the chip; and
a cover glass disposed on the frame, wherein
the frame includes a composition of two or more kinds of materials.

2. The semiconductor package according to claim 1, wherein the composition of the materials is different between a side of the substrate and a side of the cover glass of the frame.

3. The semiconductor package according to claim 1, wherein
a thermal expansion coefficient of the frame on the side of the substrate is substantially same as a thermal expansion coefficient of the substrate, and
a thermal expansion coefficient of the frame on the side of the cover glass is substantially same as a thermal expansion coefficient of the cover glass.

4. The semiconductor package according to claim 3, wherein the thermal expansion coefficient of the frame gradually changes from the side of the substrate to the side of the cover glass.

5. The semiconductor package according to claim 1, wherein the materials include any of a resin, a metal, or a ceramic.

6. The semiconductor package according to claim 1, wherein the frame and the substrate are integrally configured.

7. The semiconductor package according to claim 1, wherein
the frame has a structure having a cavity, and
the cavity has a size different between the side of the substrate and the side of the cover glass.

8. The semiconductor package according to claim 1, wherein the chip includes an imaging element.

9. A semiconductor package comprising:
a substrate;
a chip disposed on the substrate;
a frame disposed on the substrate so as to surround the chip; and
a cover glass disposed on the frame, wherein
the frame has a cavity, and
the cavity has a size different between a side of the substrate and a side of the cover glass.

10. The semiconductor package according to claim 9, wherein the size of the cavity gradually increases or decreases between the side of the substrate and the side of the cover glass of the frame.

11. The semiconductor package according to claim 9, wherein a side wall having no cavity is disposed on a side of the chip of the frame.

12. The semiconductor package according to claim 9, wherein
the frame includes a composition of two or more kinds of materials, and
the composition of the materials of the frame gradually changes from the side of the substrate to the side of the cover glass.

13. The semiconductor package according to claim 12, wherein the materials include any of a resin, a metal, or a ceramic.

14. The semiconductor package according to claim 9, wherein the chip includes an imaging element.

15. An electronic device comprising:
a substrate;
an imaging element disposed on the substrate;
a frame disposed on the substrate so as to surround the imaging element;
a cover glass disposed on the frame; and
a processor that processes a signal from the imaging element,
wherein
the frame includes a composition of two or more kinds of materials.

16. An electronic device comprising:
a substrate;
an imaging element disposed on the substrate;
a frame disposed on the substrate so as to surround the imaging element;
a cover glass disposed on the frame; and
a processor that processes a signal from the imaging element,
wherein
the frame has a cavity, and
the cavity has a size different between a side of the substrate and a side of the cover glass.
